(19) United States
(12) Patent Application Publication
(10) Pub. No.: US 2007/0138131 A1
(43) Pub. Date: Jun. 21, 2007

(54) Method of forming a patterned layer on a substrate

(76) Inventor: Dirk Burdinski, Essen (DE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/578,284

(22) PCT Filed: Nov. 1, 2004
(86) PCT No.: PCT/IB04/52253

§ 371 Date: May 4, 2006

(30) Foreign Application Priority Data
Nov. 5, 2003 (GB) 0325748.2

(51) Int. Cl. C23F 1/00; H01L 21/306; B44C 1/22; C03C 15/00

(52) U.S. Cl. 216/41; 156/345.1

(57) ABSTRACT

A method of forming a patterned self-assembled monolayer (20) on a substrate (24) by means of a soft lithographic patterning process, the method comprising: a) providing patterning means (10) for defining the required pattern of said patterned self-assembled monolayer (20); b) forming a self-assembled monolayer (20) on a surface (22) of said substrate (24); c) applying said patterning means (10) to said surface of said substrate (24), said patterning means (10) being arranged to deliver a modifier to selected areas of said substrate surface, said selected areas corresponding to said required pattern or a negative thereof, said modifier comprising a chemical and being arranged to alter at said selected areas the strength of interaction between the molecules of said selfassembled monolayer (10) and said surface of said substrate (24); and d) selectively removing or replacing areas of said self-a monolayer (20) that, after step c), exhibit a lower strength of interaction between the molecules thereof and said surface of said substrate, thereby to form a self-assembled monolayer (20) having said required pattern. The modifier may be selected to decrease or increase the strength of interaction between the molecules of the selfassembled monolayer and the uppermost surface of the substrate, as required by the process.

The invention relates to a method of forming a patterned layer on a substrate by means of a soft lithographic patterning process, such as a microcontact patterning process. The invention also relates to a patterned substrate obtained by means of the method, and to an apparatus arranged and configured to perform the method.

Patterning a metal, a metal oxide, or other material over a substrate is a common need and important process in modem technology, and is applied, for example, in microelectronics and display manufacturing. Metal patterning usually requires the vacuum deposition of a metal over the entire surface of a substrate and its selective removal using photolithography and etching techniques.

Microcontact printing is a technique for forming patterns of organic monolayers with micrometer and submicron lateral dimensions. It offers experimental simplicity and flexibility in forming certain types of patterns by printing molecules from a stamp onto a substrate. So far, most of the prior art relies on the remarkable ability of long chain alkanethiolates to form self-assembled monolayers on, for example, gold or other metals. These patterns can act as nanometer-thin resists by protecting the supporting metal from corrosion by appropriately formulated etchants, or can allow for the selective placement of fluids or solids on selected regions of the printed pattern. Patterns of self-assembled monolayers (SAM's) having lateral dimensions that can be less than 1 micrometer can be formed by using a solution of alkanethiols (the “ink”) dissolved in ethanol, and by printing them on a metal substrate using an elastomeric “stamp”. The stamp is fabricated by moulding a silicone elastomer using a master (or mould) prepared using photolithography or using other techniques such as electronbeam lithography. Patterning of the surface of such a stamp is, for example, disclosed in EP-B-0 784 543, which describes a process for producing lithographic features in a substrate layer, comprising the steps of lowering a stamp carrying a reactant onto a substrate, confining the subsequent reaction to the desired pattern, lifting the stamp and removing the debris of the reaction from the sustrate. The stamp may carry the pattern to be etched or depressions corresponding to the pattern.

Thus, microcontact printing is a soft lithographic patterning technique that has the inherent potential for the easy, fast and cheap reproduction of structured surfaces and electronic circuits with medium to high resolution: a feature size of about 100 nm or even less is currently possible, even on curved substrates.

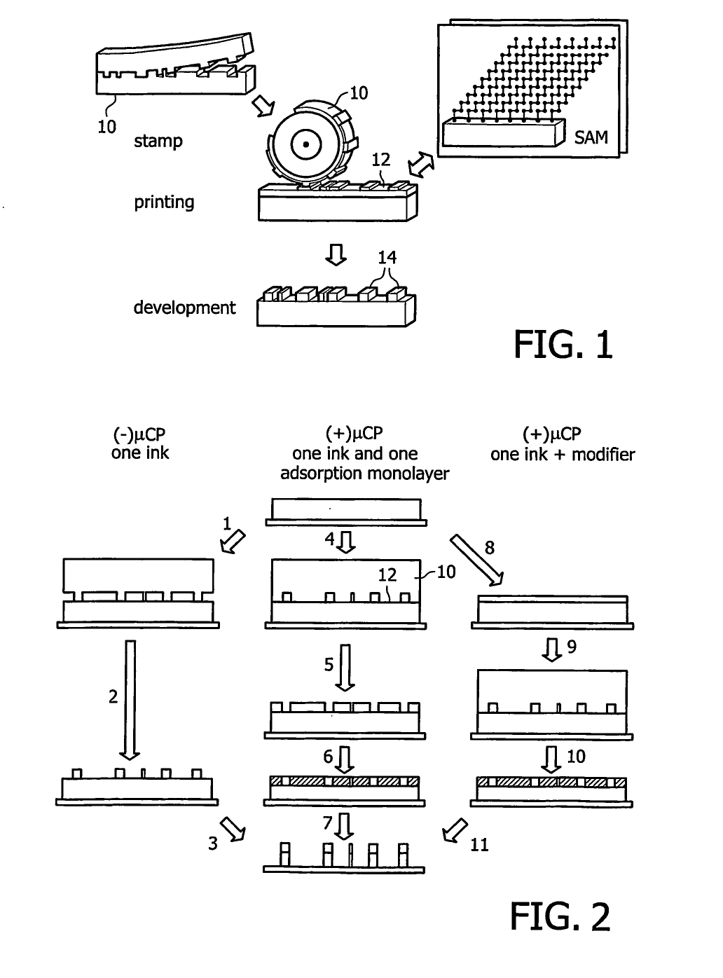

The four main steps of a microcontact process are (with reference to FIG. 1 of the drawings):
Reproduction of a stamp 10 with the desired pattern;
Loading of the stamp with an appropriate ink solution;
Printing with the inked stamp 10 to transfer the pattern 14 from the stamp 10 to the surface 12; and
If desired, development (fixation) of the pattern by means of a chemical or electromechanical process, for example, an etching process, or further deposition one or more other materials in selected areas of the printed pattern.

As explained above, printing of higher alkanethiols as ink molecules onto gold arid other metal surfaces was one of the first techniques developed (for example, U.S. Pat. No. 5,512,131; Kumar A. et al, The Use of Self-Assembled Monolayers and a Selective Etch to Generate Patterned Gold Features, Journal of the American Chemical Society, 1992.114: 9188-89; Kumar, A and G. M. Whitesides, Features of Gold having Micrometer to Centimeter Dimensions can be formed through a combination of stamping with an elastomeric stamp and an alkanethiol “ink” followed by chemical etching, Applied Physics Letters, 1993.63: 2002-4). In this case, the amphipathic alkanethiol ink molecules form a self-assembled monolayer (SAM) of deprotonated thiolates on the surface resembling the pattern of the stamp. The driving force for the formation of the SAM is the strong interaction of the polar thiolate head groups with the gold atoms (or atoms of other metals) in the uppermost surface layer, on the one hand, and the intermolecular (hydrophobic) van der Waals interaction between the apolar tail groups in the SAM, on the other hand. The combination of these two interactions results in a well ordered SAM of high stability against mechanical, physical or chemical attack. Besides the described example, other types of inks and materials may be employed to create a patterned layer of a resist material on a metal surface by means of microcontact printing. The patterned layer generated in this manner can be used as an etch resist similar to development processes in conventional (photo-) lithographic processes.

In the combination of microcontact printing with etching techniques for metal patterning, a rough distinction between two basic techniques can be made: negative microcontact printing and positive microcontact printing, and these processes will now be described in more detail.

With reference to FIG. 2 of the drawings, in a negative microcontact printing ((−)? CP)process 1, a patterned monolayer is formed on the surface of a metal layer 2 and this monolayer is used as an etch resist in a subsequent wet chemical etching step 3, and it is analogous to conventional negative photolithography techniques. In the illustrated example, a (−)? CP process is one in which in the development step material is removed selectively from those areas that have not been covered with ink in the earlier printing step 3. The material layer remains unchanged in those areas that have been covered with ink. The surface of the substrate will, after the process, be elevated in those regions that are also elevated on the surface of the stamp. In other words, it will be a mirror image of the stamp relief structure. In positive microcontact printing ((+)μCP), on the other hand, the result of the process after the development step is inverse to that obtained with (−)? CP. Thus, the surface will be elevated in those regions that are depressed in the surface structure of the stamp. Various approaches to realize a (+)? CP process are known, however, in all cases, a stamp 4 is used with a pattern which is inverted relative to the pattern on a stamp used in a respective (−)? CP process 1. Eventually, etching of the surface metal layer 7 is performed selectively in the initially contacted regions 5, as will be explained in more detail later. By its very nature, the (+)? CP process is the more difficult of the two processes described above to realise practically.

Thus, the above-described (−)μCP is most commonly used in, and a highly suitable method for, surface patterning in cases in which the ratio of the surface area of the elevated regions of the desired pattern to that of the depressed regions of the pattern (i.e. the “filling ratio” of the pattern) is high. However, if the filling ratio is significantly smaller than approximately 1, or are large non-elevated regions in the pattern, then conventional (−)μCP processes become very difficult.

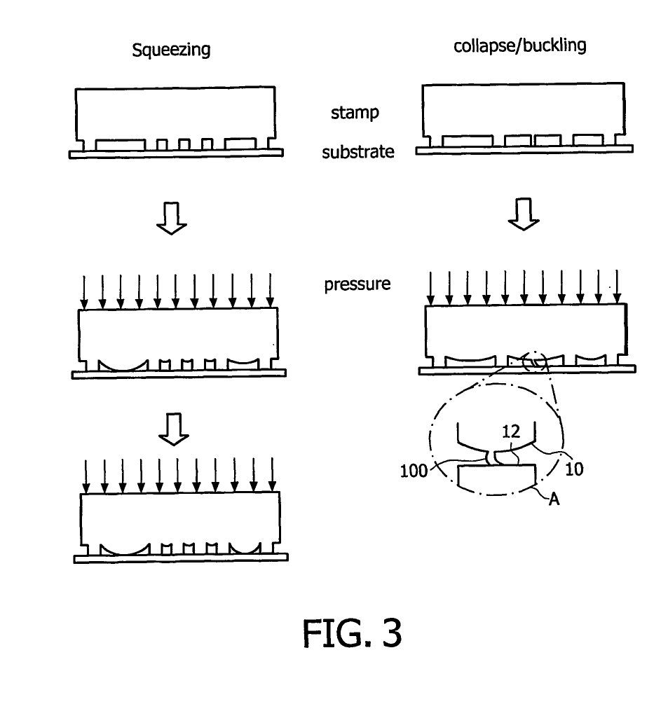

The reason for this is the fact that for a large majority of applications, the stamp material of choice is an elastomeric poly(dimethylsiloxane) (PDMS), which has a low three-dimensional stability against deformation through pneumatic or mechanical stress. In the case of patterns having a low filling ratio or having extended featureless areas, such as those encountered in the driver electronics of active matrix displays, the stamp is prone to be squeezed or collapse (buckle) under the applied pressure, as illustrated in FIG. 3 of the drawings, even if this pressure is very small. The squeezing phenomena results in unwanted contact of the depressed regions of the stamp with surface of the substrate, and thus in an undesired transfer of ink from those depressed regions of the stamp 10 to the substrate 12. Collapse or buckling of the stamp has similar consequences and causes a dramatic reduction in the maximum achievable resolution. In the subsequent development step, these additionally-contacted regions (see, for example, reference no. 100 in detail A of FIG. 3) are indistinguishable from the intentionally printed regions and will, as a consequence, translate to unwanted features. Microcontact printing of a pattern having a low filling ratio or extended featureless regions could, in theory, be achieved by means of (+)? CP, using a stamp with an inverted relief structure (see the middle diagram in FIG. 2 of the drawings). In this case, the contact area between the stamp and the substrate would again have a high filling ratio. However, in practice, such a method would rely on suitable ink molecules that permit the subsequent development step of selective etching in the contacted areas of the substrate, whereas no ink system has, thus far, been developed which allows wet chemical development of such inverted patterns directly after the printing step, although some examples of (+)? CP systems which rely on an additional process step before wet chemical etching have been reported in literature.

For example, Delamarch, E., et al, Positive Microcontact Printing, Journal of the American Chemical Society, 2002.124:3834-5, describes a two-ink method in which pentaerythritoltetrakis(3-mercaptopropionate) (PTMP) is used as a first ink in printing a gold or copper substrate with a stamp bearing an “inverted relief pattern”. This tetradentate thiol molecule forms a monolayer in the contacted regions of the substrate. In a second step, the printed substrate is immersed in a solution of a second thiol (HS(CH₂)₁₉CH₃) that forms a stable SAM preferably in the remaining uncovered portions of the substrate. This second monolayer is, in contrast to the first thiol PTMP, designed to be stable against the wet chemical etchant used during the development step and to provide good etch resistance in those regions.

In the method described in Kim, E., A. Kumar and G. M. Whitesides, Combining Patterned Self-Assembled Monolayers of Alkanethilates on Gold With Anisotropic Etching of Silicon to Generate Controlled Surface Morphologies, Journal of the Electrochemical Society, 1995.142:628-33, the ink molecules (hexadecanethiol) used in the initial printing step form a hydrophobic SAM in the contacted regions. In the following step, a different second thiol (16-mercaptohexadecanoic acid, HS(CH₂)₁₅COOH) is used to derivatize the rest of the surface, covering those areas with a hydrophilic SAM. Subsequently, a drop of an organic polymer is placed on the so-modified substrate. The polymer assembles only on the hydrophilic regions of the surface (i.e. those exposing COOH groups) and provides those regions with an enhanced stability against wet chemical etching. In the following development step, material will be etched away only in the initially printed areas that are not modified with a polymer layer and thus provide less etch resistance against the etching bath used.

The approaches described above have two main disadvantages. Firstly, they depend on the use of thiols as the ink molecules, and secondly, they rely on an additional processing step after the actual printing step, before the positive pattern can be developed by wet chemical etching.

We have now devised an improved arrangement.

A method of forming a patterned self-assembled monolayer on a substrate by means of a soft lithographic patterning process, the method comprising:
(a) providing patterning means for defining the required pattern of said patterned self-assembled monolayer;
(b) forming a self-assembled monolayer on a surface of said substrate;
(c) applying said patterning means to said surface of said substrate, said patterning means being arranged to deliver a modifier to selected areas of said substrate surface, said selected areas corresponding to said required pattern or a negative thereof, said modifier comprising a chemical and being arranged to alter at said selected areas the strength of interaction between the molecules of said self-assembled monolayer and said surface of said substrate; and
(d) removing or replacing selectively areas of said self-assembled mono layer that, after step (c)
exhibit a lower strength of interaction between the molecules thereof and said surface of said substrate, thereby to form a self-assembled monolayer having said required pattern.

Thus, the areas of the SAM having a lower strength of interaction with the surface of the substrate may be removed, or they may be replaced by different molecules. In other words, after modification, the loosely bound molecules may be replaced by other molecules, for example, by immersion of the substrate in a solution containing such other molecules.

Thus, the method according to the present invention does not require the use of inks consisting of or containing molecules such as thiols, that are able to form self-assembled monolayers. Furthermore, the pattern can be developed by (e.g. wet chemical) etching directly after the printing step without further modification.

It will be appreciated that the patterning means may be arranged to deliver the modifier to the self-assembled monolayer be contact therewith, or otherwise.

The present invention extends to a substrate having thereon a patterned self-assembled monolayer obtained by means of the method defined above, to a soft lithographic patterning apparatus arranged and configured to carry out the method as defined above, and to the use of a modifier comprising a chemical, on patterning means in a soft lithographic patterning process to alter, at selected areas of a self-assembled monolayer on a substrate, the strength of interaction between the molecules of said self-assembled monolayer and the surface of said substrate on which said self-assembled monolayer is provided, said selected areas of said self-assembled monolayer corresponding to a required pattern or a negative thereof.

The patterning means may comprise a patterned stamp defining the required pattern of said self-assembled monolayer, or the patterning means may comprise a substantially nonpatterned stamp and a mask defining the required pattern of the patterned self-assembled monolayer.

In one embodiment of the present invention, the modifier is selected to reduce the strength of the interaction between the molecules of the self-assembled monolayer and the uppermost surface of the substrate.

In an alternative embodiment of the present invention, the modifier is selected to increase the strength of interaction between the molecules of the self-assembled monolayer and the uppermost surface of the substrate.

In a preferred embodiment of the present invention, the substrate is immersed in a solution of suitable molecules, or exposed to an atmosphere containing suitable molecules, for a sufficient period of time to cause the self-assembled monolayer to be formed thereon by adsorption.

It will be well known to a person skilled in the art that adsorption is the process by which layers of a gas, liquid or solid build up on a surface, usually a solid surface. There are two types of adsorption: physisorption in which the attractive forces are purely Van der Waals, and chemisorption where chemical bonds are actually formed between the adsorbent (the material doing the adsorbing) and the adsorbate (the material being adsorbed), and the term “adsorption” herein is intended to cover both of the above types.

Alternatively, however, the self-assembled monolayer may be formed on the substrate by bringing into contact therewith a non-patterned stamp carrying the molecules of which the monolayer is to be formed.

The substrate preferably comprises a base with an additional layer of material provided thereon, wherein the self-assembled monolayer is provided on the additional layer. In one embodiment, the method may further comprise the step of etching the substrate to remove selected portions of the additional layer in accordance with the, required pattern, or deposit material in selected regions of the substrate, thereby to form an additional patterned layer on the substrate. -In fact, the present invention further extends to a substrate (24) having thereon an additional patterned layer obtained by means of the method defined above.

As stated above, the modifier comprises a chemical, selected to alter the strength of interaction between the molecules of said self-assembled monolayer and the uppermost surface of said substrate. In one embodiment, the modifier may comprise a chemical selected to alter the strength of interaction between the molecules of the self-assembled monolayer and the uppermost surface of the substrate after stimulation through an external stimulus, such as heat, electromagnetic radiation (e.g. UV or visible light), or time in the case of a slowly progressing reaction.

The self-assembled monolayer may be formed of thiol molecules, and the modifier may contain molecules of one or more of the following classes: oxidising or reducing agents, electron or atom-transfer reagents, reagents that cause formation or cleavage of a chemical bond.

In the case that the patterning means comprises a stamp, patterned or otherwise, the stamp is preferably formed of an elastomeric material, preferably a polymer, such as poly(dimethylsiloxane), and the modifier beneficially comprises a chemical having an affinity for the material of which the stamp is formed.

Thus, in the method defined above, the surface of the substrate is first covered with a suitable self-assembled monolayer. This homogenous SAM may be formed by, for example, adsorption from solution or the gas phase or by means of a preceding printing step using a non-patterned, “flat” stamp. This step followed by the actual patterning/printing step, in which a patterned stamp is brought in conformal contact with the surface of the substrate. Upon contact with the substrate, the stamp delivers a chemical (e.g. ink) or other (e.g. ultraviolet light) modifier to the contacted areas, so as to cause a local, chemical modification of the molecules in the SAM. This modification is of a kind that alters the strength of interaction between the molecules in the SAM and the uppermost material surface layer in these contacted regions. No modification occurs in the non-contact areas.

The resulting local alteration in binding strength is utilised in a subsequent development step to selectively remove the less stable parts of the monolayer, i.e. the parts which are less strongly bound to the surface of the substrate, and the underlying material layer in these areas, thereby transferring the pattern formed in the monolayer to the material layer. It will be appreciated by a person skilled in the art that the formation of a patterned self-assembled monolayer according to the invention is a useful process in and of itself, even without a subsequent etching (or deposition step) to remove or add to the underlying layer. In one embodiment, the steps of (a) removing the areas of the self-assembled monolayer in which the strength of interaction of the molecules is lowest and (b) removing selected areas of the underlying layer may be combined into a single step (as described in more detail later). However, having two discrete steps to perform these functions may increase the versatility of the invention significantly as it may, for example, permit the use of etching materials that would not necessarily be able to penetrate the areas of the SAM with the relatively weaker surface binding, but that may be useful and selective, once these areas of the SAM have been removed by means of a different solution in a previous step.

The chemical modification of the SAM in the printing step may result in a decreased binding strength of the monolayer at the contacted areas, such that the contacted areas of the monolayer (and the underlying material) are removed during a subsequent etching step. This results in a positive microcontact printing process. On the other hand, the chemical modification of the SAM in the printing step may result in an increased binding strength of the monolayer at the contacted areas, in which case the noncontacted areas of the monolayer (and underlying material) are removed during the etching step. This results in a negative microcontact printing process.

These and other aspects of the present invention will be apparent from, and elucidated with reference to, the embodiments described herein.

Embodiments of the present invention will now be described by way of examples only and with reference to the accompanying drawings, in which:

FIG. 1 is a schematic illustration of the main steps of a microcontact printing process, namely, stamp replication, inking, printing and development;

FIG. 2 is a schematic illustration of a negative and a positive microcontact printing process;

FIG. 3 illustrates schematically the squeezing (a) and collapse (b) of microcontact printing stamps having a low filling ratio caused by application of pressure during the printing step;

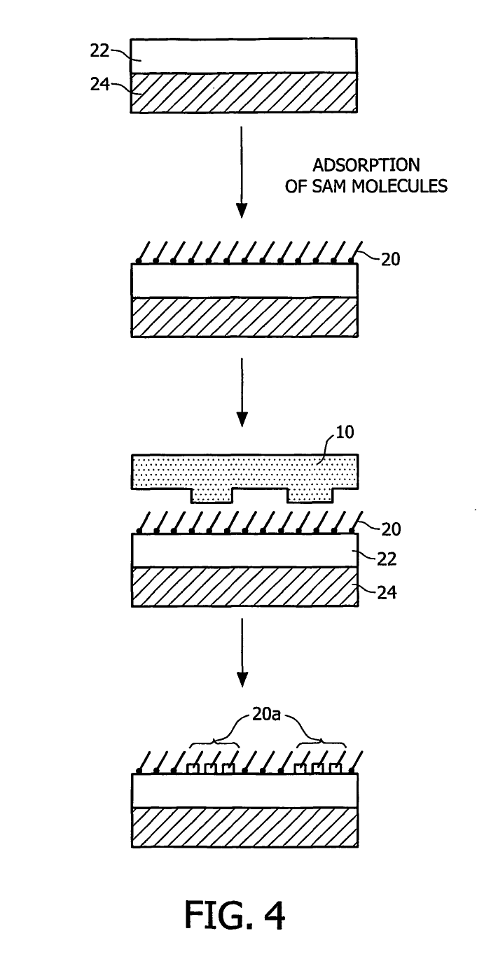

FIG. 4 illustrates schematically part of a method according to an exemplary embodiment of the invention;

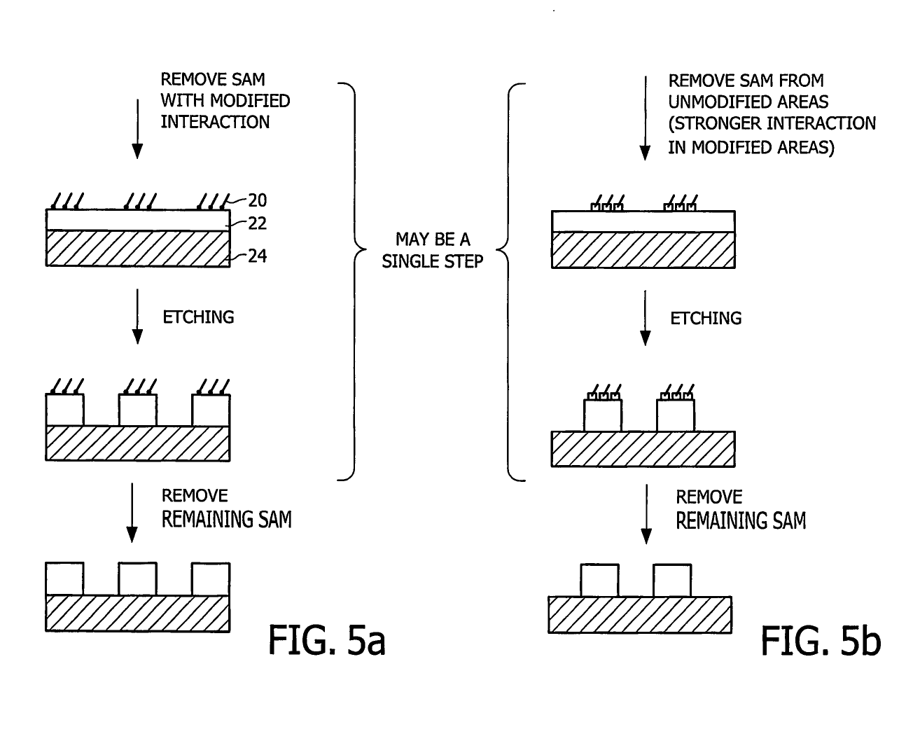

FIGS. 5a and b illustrate etching steps in a method according to two respective exemplary embodiments of the invention;

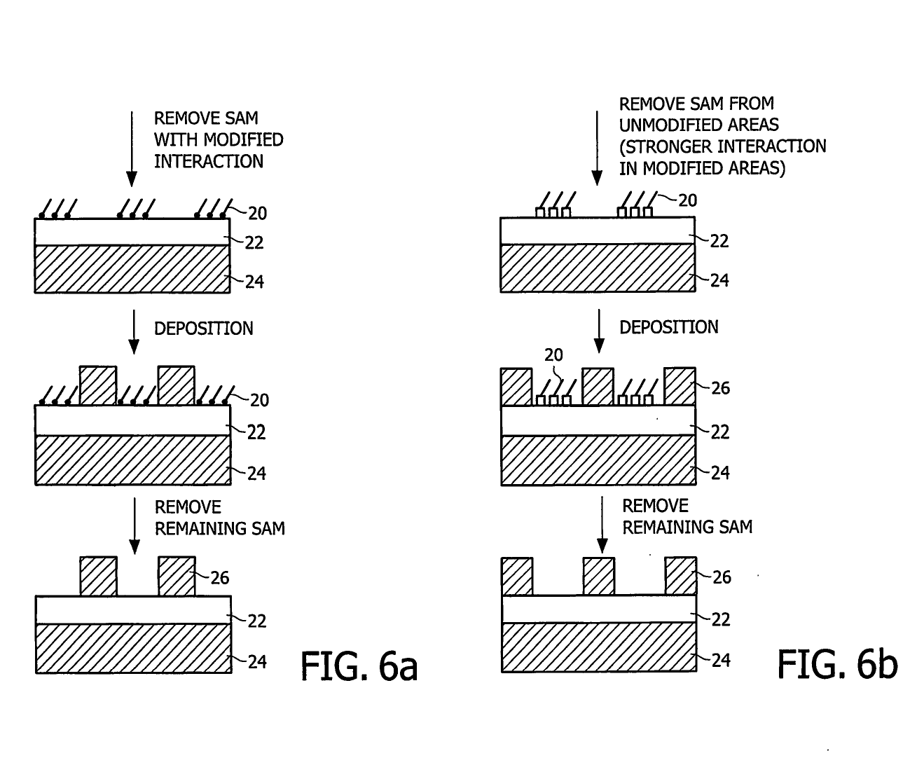

FIGS. 6a and b illustrate schematically two possible deposition steps in a method according to two alternative respective exemplary embodiments of the invention; and

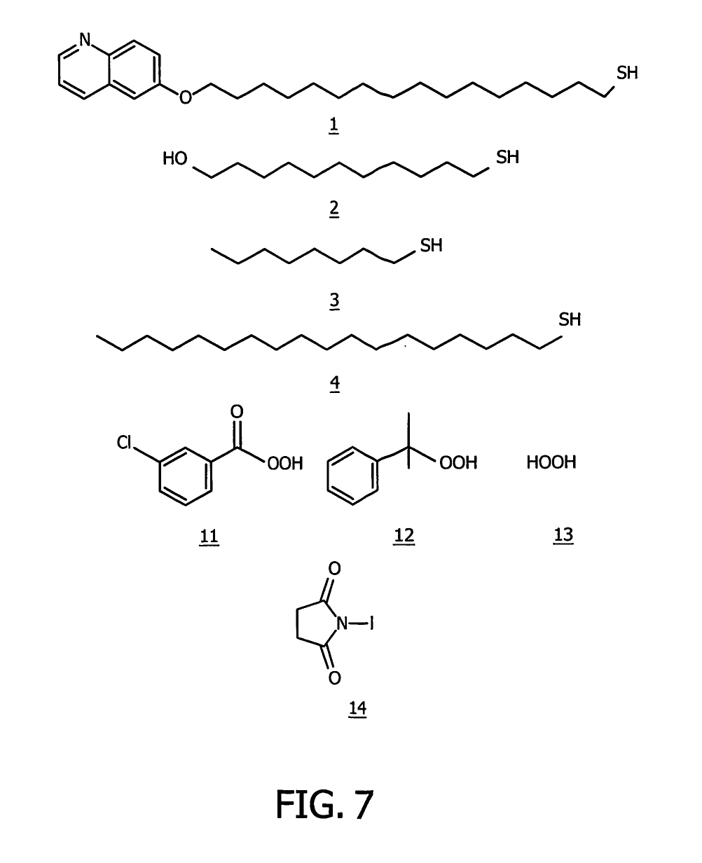

FIG. 7 illustrates molecule formulae and the numbering scheme used in the experimental examples.

For the sole purpose of clarifying various aspects of the present invention, a simple method according to an exemplary embodiment of the present invention will now be described.

If, for example, the substrate is gold, then the most suitable type of SAM-forming molecules tend to be alkanethiols or arenethiols. As explained earlier, the SAMs formed from these molecules on gold are composed of deprotonated thiolates. The driving force for the formation of the SAM are the strong interaction of the polar thiolate head groups with the gold atoms in the uppermost surface layer of the substrate, on the one hand, and the intermolecular van der Waals interaction between the apolar tail groups in the SAM, on the other hand (see FIG. 1). The combination of these two interactions results in a well ordered SAM of high stability against mechanical, physical or chemical attack.

If the strength of one of these two interactions is reduced, the stability of the SAM will decrease significantly. With respect to this example (only), the process focuses specifically on a modification of the strength of the interaction between the sulphur head group of the thiols in the monolayer and the uppermost gold surface layer (it is known in the art that oxidative attack by ambient oxidants, such as dioxygen or ozone, on the SAM mainly occurs at the sulfide head group of the thiol molecules, as will now be discussed in more detail).

It is known that exposure of alkanethiol SAMs on gold to UV light under ambient conditions causes oxidation of the thiolate sulphur to sulfoxide species RSOₙ⁻ (where n=2,3) and eventually to sulphate ion (see e.g. Zhang, Y., R. H. Terrill, and P. W. Bohn, Ultraviolet Photochemistry and ex Situ Ozonolysis of Alkanethiol Self-Assembled Monolayers on Gold. Chemistry of Materials, 1999.11:2191-8). The reaction of alkanethiol SAMs with ozone in the dark has further been shown to yield the same sulfoxide species. More -importantly, simple exposure of these monolayers to the ambient causes analogous oxidation products. The rate of air oxidation seems to depend strongly on the kind of substrate and its surface structure, the type of alkanethiols, and the order in the particular monolayer (see e.g. Lee, M.-T., et al., Air Oxidation of Self-Assembled Monolayers on Polycrystalline Gold: The Role of the Gold Substrate. Langmuir, 1998.14:6419-23).

Independently of the mechanism used to induce oxidation, the formed suloxide species RSOₙ⁻ induce defects in the SAM due to structural changes including a different tilt angle of the oxidised molecules against the surface normal. The combination of these introduced defects with the lower gold binding energy of the oxidised species compared to that of the respective sulfides results in a dramatically enhanced exchange rate with alkane thiols in ethanolic solution. In oxidised regions the monolayer may even be simply washed off with aqueous or alcoholic solutions.

From this, it can be concluded that SAM stability in the above-described combination is the result of a number of factors, including a sulphur-gold interaction strong enough to guide assembly, steric protection of the Au—S interface by adsorbate alkyl chains, and the existence of multiple intermolecular interactions. Oxidative damage by oxygen transfer oxidants, such as dioxygen or ozone, occurs preferably at inherent monolayer defect sites; attack is directed toward the sulphur head group yielding sulfoxide species RSOₙ⁻ (n=2,3) as the main products. These products are less strongly bound to the gold surface, desorb easily in polar solvents and, consequently, allow the growth of microscopic defects to a macroscopic scale. Long chain length SAMs oxidise much more slowly than shorter ones because of the increased difficulty for the active oxidant species to penetrate the closely packed alkyl chain structure.

Thus, the known sensitivity of alkanethiol SAMs on gold against oxygen transfer agents, such as peroxo compounds, can be utilised for the area selective oxidative alteration of the binding interaction of the thiol head group to the gold surface.

Referring to FIG. 4 of the drawings, in this example, a SAM 20 composed of suitable alkanethiol molecules is formed on a flat gold layer 22 on a substrate 24 either by printing with a flat, nonpatterned stamp inked with these thiol molecules, prior to stamping, or by immersing the substrate in a solution of the thiol molecules, or exposing the substrate to an atmosphere containing such molecules, for a prolonged time. Subsequently, a patterned stamp 10 is inked with a peroxo compound that is suitable to oxidise the thiol head group of the adsorbed thiolates RS⁻ to respective sulfoxo derivatives RSOₙ⁻ (n=2,3). When the stamp 10 is brought into contact with the SAM-covered substrate 24, the peroxo species will be transferred to the surface of layer 22 on the substrate. In these regions 20a, the peroxo species will penetrate the hydrophobic region of the SAM. It will then transfer an oxygen atom to a sulphur head group of the surface-bound thiolates and oxidise it according to equation:
RS—[Au]_{surface}+nR′OOH→RSOₙ−[Au]_{surface}+nR′OH
The produced SAM of oxidised thiolates, thus a monolayer of sulfonite species, is bound to the gold surface less strongly than the initial SAM of thiolates. It also has a different structure. As a result, and referring to FIG. 5a of the drawings, this modified monolayer is less resistant to wet chemical etching by standard gold etchants, such as thiosulfate-based etching baths, which will be known to a person skilled in the art. Thus, in the following etching step (5) the SAM 20 and gold layer 22 is removed from those regions that have been modified by printing with the peroxo ink, and it will not be removed from the unmodified regions, which are protected by an etch resistant SAM 20 of unoxidised thiolates, which may subsequently also be removed (although this is not essential).

Referring to FIG. 5b of the drawings, in an alternative embodiment, the modifier or “ink” may be selected to strengthen the bond between the SAM molecules and the layer 22 on the substrate. In this case, after the stamp 10 has been brought into contact with the SAM 20, an etching step is employed to remove the SAM 20 and the layer 22 from those regions that have not been modified by the printing step. The SAM 20 and the layer 22 may be removed in a simple etching step or as two discrete steps as explained above. Once again, the remaining SAM may subsequently be removed.

Referring to FIGS. 6a and 6b of the drawings, in yet another embodiment of the invention, the patterned layer on the substrate 24 may be formed by depositing another material 26 (which may or may not be the same as the layer 22) in the regions, where the SAM has been removed. In FIG. 6a, the case is illustrated where the ink is selected to weaken the bond between the SAM molecules and the layer 22 (as described with reference to FIG. 5a), whereas in FIG. 6b the case is illustrated where the ink is selected to strengthen that bond (as described with reference to FIG. 5b).

Although the general example described above and in the experimental examples described hereinafter are related to the metalthiol substrate-ink system, it will be understood by a person skilled in the art that the present invention is not intended to be limited to this particular system. The present invention is rather applicable to most, if not all, ink-substrate systems, in which the interaction between the ink and the substrate can be modified by a suitable modifier. Further, the modifier need not necessarily be chemical but may instead be, for example, radiation which is guided selectively to the contact areas by a substantially transparent stamp. This latter application could make use of a stamp as a light guide to perform a photolithographic process using a known lithographic shadow mask.

Significant, general advantages of the present invention include:
the ability to use the invention in a (+)? CP method, especially in the case of patterns having a low filling ratio or extended featureless areas, such that the problems (such as squeezing and collapse/buckling), which may otherwise occur if a(−)? CP method has to be used, can be avoided.
In the method according to one aspect of the present invention, the SAMs used as etch resists in the final development step can be formed from a solution or the gas phase. SAMs formed in this manner are known to haw a structure with a higher degree of order and less defects. They thus have a better etch resistance than those formed by means of a stamping process, thereby providing an improved selectivity and resolution. However, on the other hand, if rapid patterning is required, a sufficiently homogeneous SAM may be formed by printing with a flat stamp in a matter of seconds. So the method of the present invention is highly flexible and adaptable to requirements.
The “ink” (if a chemical is used in the printing step) is not required to consist of molecules that form a monolayer on the surface of the substrate, because the ink is required to modify an existing monolayer instead. This particular aspect of the present invention provides a significant distinction from known ? CP methods, and there are a number of advantages associated with this particular feature, which include:
   When PDMS is used as the stamp material—as is the case in most known applications—there is a restriction to very few solvents such as ethanol, that can be used for the ink solution, which restricts the kinds of monolayer-forming molecules that can be used, as they have to be soluble in this solvent. In the present invention, this restriction does not exist, since for the formation of solutionadsorbed monolayers, a much larger variety of solvents is applicable. For SAMS formed from the gas phase no such restriction exists at all.
   With the method of the invention, a virtually endless number of ink molecules may be used, as long as they have the ability to modify the interaction between the molecules forming the monolayer and the substrate surface. Thus, problems characteristic to inks used in known ? CP systems, such as surface spreading and gas phase diffusion of ink molecules, may be less significant and can be varied and fine-tuned more easily in the present invention. In addition, SAM-forming inks which are known to show a high level of surface spreading can be readily used in the method of the present invention to form the homogeneous SAM that is to be modified in the second patterning step, because spreading is not an issue in the formation of the homogenous SAM.
   The ink may contain molecules of any of the following classes: oxidising or reducing agents, electron- or atom-transfer reagents, reagents that cause formation or cleavage of a chemical bond (including weak bonds such as hydrogen bonds or electrostatic bonds).
   The “tail group” of the ink molecules (i.e. the part of the ink molecules that has only slight, if any, influence on the chemical modification of the molecules in the monolayer) is no longer important with regard to the quality of the monolayer. Its structure can, therefore, be freely fine-tuned so as to achieve a good affinity of the ink molecules for the stamp material and allow them to penetrate the SAM easily.
   In the case where less etch resistant portions of the monolayer are formed by the printing step (i.e. if the ink reduces the interaction of the molecules in the monolayer with the substrate material), then the ink transfer does not need to be quantitative (i.e. even if not all of the molecules in the monolayer are being modified by the ink, the integrity of the monolayer will still be decreased to such an extent, that it will be sufficiently sensitive to the etching liquid.
Ink molecules can be used that have a high affinity to PDMS. Therefore, the stamp can, in principle, be re-used without re-inking for multiple stamping steps.
In contrast to known systems, the method of the present invention does not require an additional process step after printing and before the development via chemical etching.

In addition, for the most commonly-used thiol-SAM-based systems, one particular advantage of the present invention is that the ink molecules are no longer oxygen-sensitive. Thiols are easily oxidised by oxygen from the ambient surroundings and, as a result, form insoluble precipitates, that may appear as solids on the surface of the stamp. When this happens, the stamp can no longer be used. In the present invention, thiol inks do not need to be used for the stamping step (although they can still be used to form the initial homogenous SAM).

### EXPERIMENTAL EXAMPLES

The experimental examples given below cover only a very small range of possible metal-monolayer-ink combinations. All systems are based on thiol inks, which should—as stated above already—not be understood as a restriction of the possible application of the new method to these systems.

Example 1 is a practical example of the above described general example using a mixed aliphatic-aromatic thiol monolayer molecule (1) with a basic endgroup on gold and 3-chloroperoxybenzoic acid, thus an oxygen transfer oxidant, as the ink. In general a monolayer with a basic endgroup seems to be advantageous in combination with a peracid. We have also used peroxo compounds 12 (cumene hydroperoxide) and 13 (hydrogen peroxide), but the obtained resolution was in all examined cases lower than that obtainable with 11.

Example 2 describes the use of an alternative thiol monolayer molecule 2 in combination with the peroxo acid 11 as the ink 2 is a hydrophilic hydroxyalkanethiol that demonstrates, that even with acidic peroxo inks a basic monolayer is not a necessity.

In example 3 the same monolayer is used as in example 1, but a different atom transfer reagent (N-iodosuccinimide, 14) is used as the ink. This example demonstrates that a thio monolayer system can also be combined with oxidizing inks that are no oxygen transfer agents.

Example 4 shows the application of the system used in example 1 on silver-alloy substrates instead of gold and with the additional difference that octane thiol 3 was used instead of 1. The silver layer is about 10 times as thick as the gold layer used in example 1.

### Example 1

A silicium wafer was modified with an about 500 nm thick silicium oxide layer, a titanium adhesion layer (5 nm, sputtered) on top, and finally with a gold layer with a thickness or 20 nm (also sputtered). A sample with a size of about 1×2 cm² was cleaned by rinsing the gold surface with water, ethanol and r-heptane. It was further exposed to an argon plasma (0.25 mbar Ar, 300 W) for 5 min. It was immersed in a solution of thiol 1 in ethanol (0.02 molar) to form s SAM of 1 on gold. Immersion times between 0.5 and 24 hours were tested and did not make a difference in the results. After removing the substrate from this solution it was thoroughly rinsed with ethanol to remove all excess thiol solution. The substrate was dried in a stream of nitrogen gas and thereafter ready for printing.

A PDMS stamp with the desired relief structure was immersed in an ink solution of 11 in ethanol (0.02 M, prepared from 11-HCl and KOH (1:1)) for at least 10 minutes. Inking times were varied between 10 min and 10 hours with no difference in the result. After inking, the stamp was removed from the ink solution and washed thoroughly with ethanol to remove all excess ink solution. It was subsequently dried in a stream of nitrogen gas for at least 30 seconds.

The patterned side of the stamp was brought in conformal contact with the prepared gold substrate applying a light pressure for at least 10 seconds. After removal of the stamp, the substrate was immersed in an etching bath composed of potassium hydroxide (1.0 M), potassium thiosulfate (0.1 M), potassium ferricyanide (0.01 M), potassium ferrocyanide (0.001 M) and octanol at half saturation. After etching for about 15 minutes a clear pattern was observed in the gold layer. Gold was quantitatively etched away in the contacted areas, but unchanged in the non-contact areas. An inversed pattern was obtained when compared to a reference sample patterned via conventional (−)μCP using the same stamp pattern.

### Example 2

A gold substrate was prepared as described in Example 1, except that a solution of 2 in ethanol was used instead of a solution of 1 in ethanol. Printing and etching were performed as described in Example 1. After etching for about 15 minutes a clear pattern was observed in the gold layer. Gold was quantitatively etched away in the contacted areas, but unchanged in the non-contact areas. An inverted pattern was obtained when compared to a reference sample patterned via conventional (−)μCP using the same stamp pattern.

### Example 3

A gold substrate was prepared and covered with a mono layer of 1 as described in Example 1. Printing was performed as described in Example 1, except that an ink solution containing Siodosuccinimide 14 (0.02 M) instead of 11 was used. Etching was performed as described in Example 1. After etching for about 15 minutes a clear pattern was observed in the gold layer. Gold was quantitatively etched away in the contacted areas, but unchanged in the noncontact areas. An inverted pattern was obtained when compared to a reference sample patterned via conventional (−)μCP using the same stamp pattern.

### Example 4

A glass plate was covered with a molybdenum-chrome adhesion layer (20 nm sputtered MoCr (97/3)) and a 200 nm thick APC layer on top (APC=Ag(98.1%), Pd(0.9%), Cu(1.0%), sputtered). A sample with a size of about 1×2 cm² was cleaned by rinsing the APC surface with water, ethanol and mheptane. It was ftnther. exposed to an argon plasma (0.25 mbar Ar, 200 W) for 3 min. It was immersed in a solution of thiol 3 in ethanol (0.02 molar) to form a SAM of 3 on APC. Immersion times between 0.5 and 24 hours were tested and did not make a difference in the results. After removing the substrate from this solution it was thoroughly rinsed with ethanol to remove all excess thiol solution. The substrate was dried in a stream of nitrogen gas and thereafter ready for printing.

A PDMS stamp with the desired relief structure was immersed in an ink solution of 11 in ethanol (0.02 M) for at least 10 minutes. Inking times were varied between 10 min and 10 hours with no difference in the result. After inking, the stamp was removed from the ink solution and washed thoroughly with ethanol to remove all excess ink solution. It was subsequently dried in a stream of nitrogen gas for at least 20 seconds.

The patterned side of the stamp was brought in conformal contact with the prepared APC substrate applying a light pressure for at least 10 seconds. After removal of the stamp, the substrate was immersed in an acidic etching bath composed of nitric acid (65%), phosphoric acid (85%), and water (12/36/52). After etching for about 2 minutes a clear pattern was observed in the substrate. APC and MoCr were quantitatively etched away in the contacted areas, but unchanged in the noncontact areas.

Source and Synthesis of Compounds

3-Chloroperoxybenzoic acid (11), cumene hydroperoxide (12), hydrogen peroxide (13), and octadecane thiol (14) were purchased from Aldrich. 6-(16-Mercaptohexadecyloxy)quinoline hydrochloride (1-HCl) and 11-hydroxyundecanethiol (2) were synthesized as described below.

### Synthesis of 6-(16-mercaptohexadecyloxy)quinoline hydrochloride (1-HCl)

Sodium hydride. (0.77 g, 55-65%, min. 17.6 mmol) is added to a mixture of 6-hydroxyquinoline (3.09 g, 31.3 mmol) and 40 mL DMF. The mixture is stirred overnight and then 7.50 g 1,16-dibromohexadecane (19.5 mmol, containing a trace of hexadecyl bromide) is added. The mixture is stirred for 4 days, then worked up with water and toluene. The toluene layer is rotary evaporated and the residue is chromatographed on silicagel to give 3.50 g (7.81 mmol, 37% based on hydroxyquinoline) of 6-16-bromohexadecyloxy)-quinoline. NMR (CDCh): 1.1-1.6 (m, 26H), 1.85 (m, 2H), 3.4 (t, 2H), 4.05 (t, 2H), 7.0 (m, 1H), 7.35 (m, 2H), 8.0 (m, 2H), 8.75 (m, 1H).

To a mixture of sodium hydride (860 mg, min. 19.7 mmol) and 25 mL tetrahydrofurane (THF) there is added with cooling thioacetic acid (2.12 g, 27.9 mmol). After stirring for 1 h at RT the produce obtained above, dissolved in 25 mL THF, is added and the mixture is stirred at RT overnight, then heated for 5 h at 550 C. Workup with water and toluene gives a crude product which is chromatographed on 100 g silicagel. The product elutes with toluene containing some tert.-butylmethyl ether (TBME). The product fractions are combined, rotary evaporated and the residue is recrystallized from ethanol to give 2.81 g of light-brown solid (6.34 mmol, 81%). NMR (CDCl₃): 1.1-1.6 (M, 26H) 1.85 (m, 2H), 2.3 (s, 3H), 2.85 (t, 2H), 4.05 (t, 2H), 7.0 (m, 1H), 7.35 (m, 2H), 8.0 (m, 2H), 8.75 (m, 1H).

This product is heated under reflux for 7 h in a mixture of 50 mL ethanol and 5 mL conc. hydrochloric acid. On cooling the product precipitates. Filtering and washing with 90% methanol gives 2.40 g of the desired product as the hydrochloride (5.49 mmol, 87%). NMR (CDCl₃): 1.1-1.6 (m, 27H), 1.85 (m, 2H), 2.5 (q, 2H), 4.1 (t, 2H), 7.25 (d, 1H), 7.65 (dd, 1H), 7.8 (dd, 1H), 8.65 (d, 1H), 8.8 (m, 2H).

### 1,16-dibromohexadecane

A solution of 1,6-dibromohexane (137.4 g, 0.56 mol) in 100 mL THF is added slowly to magnesium (27.2 g, 1.13 mol) in 300 mL THF with cooling (maximum internal temperature 50° C). The mixture is stirred for 2 h at 65° C., then added as a warm solution over a 4 h period to a mixture of 1,5-dibromopentane (300 g, 1.30 mol), 250 mL THF and 50 mL 0.1 N—Li₂CuCl₄ in the THF with ice-cooling (maximum internal temperature 15° C.). The mixture is heated for 1 h at 50-60° C., then cooled and 1,5-dibromopentane (109 g, 0.47 mol), 300 mL THF, 1.30 g lithiut chloride, and 2.00 g cupric chloride are added.

A solution of 1,6-dibromohexane (180 g, 0.73 mol) in 250 mL THF is added slowly to magnesium (42 g, 1.75 mol) in 350 mL THF with ice-cooling (maximum internal temperature 30° C.). The mixture is stirred overnight, then warmed for 3 h at 50° C., then added as a warm solution over a 3 h period to the reaction mixture above with ice-cooling (maximum internal temperature 20° C.). The mixture is stirred overnight, then rotary evaporated in order to remove some of the THF. To the remaining suspension there is added water and TBME. The layers are separated, the organic layer is washed with water, then rotary evaporated. Kugelrohr distillation of the residue gives 37.4 g of product which contains some impurities (97.3 mmol, 7% based on 1,6-dibromohexane). Part of the product (17 g) is recrystallized twice from heptane (cooling to −15° C.) to give 7.5 g of pure product.

### Synthesis of 11-hydroxyundecanethiol (2)

A mixture of 50 g of 11-bromoundecanol, 18.3 g of thiourea and 11 g of water was stirred in an oil bath of 110° C. for 2 h under a nitrogen atmosphere. After addition of 160 ml of a 10% aqueous sodium hydroxide solution, stirring was continued for 2 h at the same temperature. 40 g of ice were added followed by 40 ml of concentrated hydrochloric acid solution. The mixture was extracted with 200 ml of diethyl ether. The ethereal solution was subsequently extracted with 150 ml of water and 150 ml of brine and dried over magnesium sulphate. 29 g of the product (71%) were obtained after evaporation of the diethyl ether and crystallization from 200 ml of hexane.

It will be appreciated by a person skilled in the art that there are several different combinations of monolayer material and modifier envisaged, and the invention is not intended to be limited with regard to specific combinations. Rather, the invention lies in the selection of modifier based on its ability to alter the strength of interaction between the molecules of said self-assembled monolayer and the uppermost surface of said substrate.

It should be further noted that the above-mentioned embodiment illustrates rather than limits the invention, and that those skilled in the art will be capable of designing many alternative embodiments without departing from the scope of the invention as defined by the appended claims. In the claims, any reference signs placed in parentheses shall not be construed as limiting the claims. The, word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. A method of forming a patterned self-assembled monolayer on a substrate by means of a soft lithographic patterning process, the method comprising:
a) providing patterning means for defining the required pattern of said patterned self-assembled monolayer
b) forming a self-assembled monolayer on a surface of said substrate
c) applying said patterning means to said surface of said substrate said patterning means being arranged to deliver a modifier to selected areas of said substrate surface, said selected areas corresponding to said required pattern or a negative thereof, said modifier comprising a chemical and being arranged to alter at said selected areas the strength of interaction between the molecules of said self-assembled monolayer and said surface of said substrate and
d) selectively removing or replacing areas of said self-assembled monolayer that, after step c), exhibit a lower strength of interaction between the molecules thereof and said surface of said substrate, thereby to form a self-assembled monolayer shaving said required pattern.

2. A method according to claim 1, wherein said patterning means comprises a patterned stamp defining the required pattern of said patterned self-assembled monolayer.

3. A method according to claim 1, wherein said patterning means comprises a substantially non-patterned stamp and a mask defining the required pattern of said patterned self-assembled monolayer.

4. A method according to claim 1, wherein said modifier is selected to reduce the strength of the interaction between the molecules of the self-assembled monolayer and said substrate surface.

5. A method according to claim 1, wherein said modifier is selected to increase the strength of the interaction between the molecules of the self-assembled monolayer and said substrate surface.

6. A method according to claim 1, wherein said self-assembled monolayer is formed by immersing the substrate in a solution of molecules, or exposing the substrate to an atmosphere containing molecules for a sufficient amount of time to cause the self-assembled monolayer to be formed thereon by adsorption.

7. A method according to claim 1, wherein the self-assembled monolayer is formed on the substrate by bringing into contact therewith a non-patterned stamp carrying the molecules of which the monolayer is to be formed.

8. A method according to claim 1, wherein said substrate: comprises a base with an additional layer of material provided thereon, said self-assembled monolayer being provided on said additional layer.

9. A method according to claim 8, further comprising the step of etching said substrate to remove selected portions of said additional layer in accordance with said required pattern, thereby to form an additional patterned layer on the substrate.

10. A method according to claim 1, further comprising the step of depositing material in selected regions of said substrate in accordance with said required pattern, thereby to form an additional patterned layer on said substrate.

11. A method according to claim 1, wherein said modifier comprises a chemical, selected to alter the strength of interaction between the molecules of said self-assembled monolayer and said substrate surface.

12. A method according to claim 11, wherein said modifier comprises a chemical, selected to alter the strength of interaction between the molecules of said self-assembled monolayer with time, or in response to an external stimulus.

13. A method according to claim 12, wherein said external stimulus comprises electromagnetic radiation.

14. A method according to claim 13, wherein said external stimulus comprises ultra-violet radiation or visible light.

15. A method according to claim 1, wherein said self-assembled monolayer comprises thiol molecules.

16. A method according to claim 1, wherein the modifier contains molecules of one or more of the following classes: oxidising or reducing agents, electron- or atom-transfer reagents, reagents that cause formation or cleavage of a chemical bond.

17. A method according to claim 2, wherein said stamp is formed of an elastomeric material.

18. A method according to claim 2 wherein said stamp is substantially transparent to electromagnetic radiation.

19. A method according to claim 17, wherein said stamp is formed of a polymer.

20. A method according to claim 19, wherein said stamp is formed of poly(dimethylsiloxane).

21. A method according to claim 2, wherein the modifier comprises a chemical having an affinity for the material of which said stamp is formed.

22. A substrate having thereon a patterned self-assembled monolayer obtained by means of the method according to claim 1.

23. A substrate (having thereon an additional patterned layer obtained by means of a method according to claim 9.

24. Soft lithographic patterning apparatus arranged and configured to perform the method of anyone of claim 1.

25. Use of a modifier, comprising a chemical, on a patterning means in a soft lithographic patterning process to alter, at selected areas of a self-assembled monolayer on a substrate the strength of interaction between the molecules of said selected areas of said self-assembled monolayer and the surface of said substrate on which said self-assembled monolayer is provided, said selected areas of said self-assembled monolayer corresponding to a required pattern or a negative thereof.
